(19) United States
(12) Patent Application Publication
(10) Pub. No.: US 2009/0261712 A1
(43) Pub. Date: Oct. 22, 2009

(54) ORGANIC LIGHT EMITTING DIODE DISPLAY AND METHOD FOR MANUFACTURING THE SAME

(75) Inventors: Jun-Ho CHOI, Yongin-si (KR); Sang-Pil LEE, Anyang-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 12/244,524

(22) Filed: Oct. 2, 2008

(30) Foreign Application Priority Data
Apr. 18, 2008 (KR) 10-2008-0036224

(51) Int. Cl. H01J 1/62; H01L 51/56

(52) U.S. Cl. 313/504; 438/29; 257/E51.021

(57) ABSTRACT

The present invention relates to an organic light emitting device and a manufacturing method. The organic light emitting device includes a first signal line and a second signal line crossing each other, a switching thin film transistor connected to the first signal line and the second signal line, a driving thin film transistor connected to the switching thin film transistor, an organic layer covering the first signal line, the second signal line, the switching thin film transistor, and the driving thin film transistor, a pixel electrode disposed on the organic layer and connected to the driving thin film transistor, a pixel-defining layer disposed on the organic layer and enclosing the pixel electrode, a blocking film including an inorganic insulating layer and covering the pixel-defining layer and edges of the pixel electrode, a light emitting member disposed on the pixel electrode and a common electrode disposed on the light emitting member.

### CROSS-REFERENCE TO RELATED APPLICATION

This application claims priority from and the benefit of Korean Patent Application No. 10-2008-0036224, filed on Apr. 18, 2008, which is hereby incorporated by reference for all purposes as if fully set forth herein.

### BACKGROUND OF THE INVENTION

1. Field of the Invention

The present invention relates to an organic light emitting device and a manufacturing method thereof.

2. Discussion of the Background

The recent trend toward lightweight and thin personal computers and television sets has increased the requirements for lightweight and thin display devices, and flat panel displays such as liquid crystal displays (LCDs) that satisfy such requirements are being substituted for conventional cathode ray tubes (CRTs).

However, because the LCD is a passive display device, an additional back-light as a light source is needed, and the LCD has various problems such as a slow response time and a narrow viewing angle.

Among flat panel displays, an organic light emitting device has recently been the most promising as a display device that solves these problems.

An organic light emitting device includes two electrodes and an organic light emitting layer disposed between the two electrodes. One of the two electrodes injects holes into the light emitting layer and the other injects electrons into the light emitting layer. The injected electrons and holes are combined to form excitons, and the excitons emit light as they discharge energy.

Because the organic light emitting device is a self-emissive display device, an additional light source is not necessary. Therefore, the organic light emitting device has lower power consumption, as well as a high response speed, a wide viewing angle, and a high contrast ratio.

Generally, in the organic light emitting device, thin film transistors and metal wiring are formed on a substrate, and a flat organic layer to reduce protrusions and depressions caused by the thin film transistors and metal wiring is formed on the thin film transistors and metal wiring. An organic light emitting member is formed on the flat organic layer. However, the organic layer is made of an organic material and moisture or impurities may exist therein. The impurities or the moisture may penetrate into the organic light emitting member and cause pixel shrinkage.

### SUMMARY OF THE INVENTION

The present invention provides an organic light emitting device in which impurities or moisture existing in an organic layer or color filters may be prevented from penetrating into the emitting member and causing pixel shrinkage.

Additional features of the invention will be set forth in the description which follows, and in part will be apparent from the description, or may be learned by practice of the invention.

The present invention discloses an organic light emitting device including a first signal line and a second signal line crossing each other, a switching thin film transistor connected to the first signal line and the second signal line, a driving thin film transistor connected to the switching thin film transistor, an organic layer covering the first signal line, the second signal line, the switching thin film transistor, and the driving thin film transistor, a pixel electrode disposed on the organic layer and connected to the driving thin film transistor, a pixel-defining layer disposed on the organic layer and enclosing the pixel electrode, a blocking film including an inorganic insulating layer and covering the pixel-defining layer and edges of the pixel electrode, a light emitting member disposed on the pixel electrode, and a common electrode disposed on the light emitting member.

The present invention also discloses a method for manufacturing an organic light emitting device including forming wiring and a thin film transistor on an insulation substrate, forming an organic layer on the wiring and the thin film transistor, forming a pixel electrode on the organic layer and connected to the thin film transistor, forming a pixel-defining layer on the organic layer and enclosing the pixel electrode, forming a blocking film covering the pixel-defining layer and edges of the pixel electrode, forming an organic light emitting member on the pixel electrode, and forming a common electrode on the organic light emitting member.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is an equivalent circuit diagram of an organic light emitting device according to an exemplary embodiment of the present invention.

FIG. 2 is a layout view of an organic light emitting device according to an exemplary embodiment of the present invention.

FIG. 3 is a cross-sectional view of the organic light emitting device shown in FIG. 2 taken along line III-III.

FIG. 4, FIG. 6, and FIG. 8 are layout views sequentially showing the manufacturing method of the organic light emitting device shown in FIG. 2 and FIG. 3.

FIG. 5 is a cross-sectional view of the organic light emitting device shown in FIG. 4 taken along line V-V.

FIG. 7 is a cross-sectional view of the organic light emitting device shown in FIG. 6 taken along line VII-VII.

FIG. 9 is a cross-sectional view of the organic light emitting device shown in FIG. 8 taken along line IX-IX.

FIG. 10 is a cross-sectional view showing a manufacturing step following that shown in FIG. 9.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

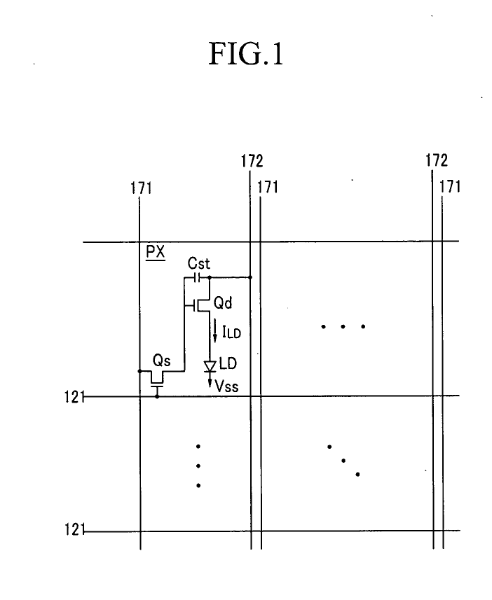

Now, an OLED according to an exemplary embodiment of the present invention will be described in detail with reference to FIG. 1.

FIG. 1 is an equivalent circuit diagram of an organic light emitting device according to an exemplary embodiment of the present invention.

Referring to FIG. 1, an organic light emitting device according to the present exemplary embodiment includes a plurality of signal lines 121, 171, and 172, and a plurality of pixels PX connected thereto and arranged substantially in a matrix.

The signal lines include a plurality of gate lines 121 to transmit gate signals (or scanning signals), a plurality of data lines 171 to transmit data signals, and a plurality of driving voltage lines 172 to transmit a driving voltage. The gate signal lines 121 extend substantially in a row direction and are substantially parallel to each other, and the data lines 171 and the driving voltage lines 172 extend substantially in a column direction and are substantially parallel to each other.

Each pixel PX includes a switching transistor Qs, a driving transistor Qd, a storage capacitor Cst, and an organic light emitting diode LD.

The switching transistor Qs has a control terminal connected to one of the gate lines 121, an input terminal connected to one of the data lines 171, and an output terminal connected to the driving transistor Qd. The switching transistor Qs transmits data signals applied to the data line 171 to the driving transistor Qd in response to a gate signal applied to the gate line 121.

The driving transistor Qd has a control terminal connected to the switching transistor Qs, an input terminal connected to the driving voltage line 172, and an output terminal connected to the organic light emitting diode LD. The driving transistor Qd drives an output current I_{LD} having a magnitude dependent on the voltage between the control terminal and the input terminal thereof.

The capacitor Cst is connected between the control terminal and the input terminal of the driving transistor Qd. The capacitor Cst stores a data signal applied to the control terminal of the driving transistor Qd and maintains the data signal after the switching transistor Qs turns off.

The organic light emitting diode LD has an anode connected to the output terminal of the driving transistor Qd and a cathode connected to a common voltage Vss. The organic light emitting diode LD emits light having an intensity dependent on an output current I_{LD} of the driving transistor Qd to display images.

The switching transistor Qs and the driving transistor Qd are n-channel field effect transistors (FETs). However, at least one of the switching transistor Qs and the driving transistor Qd may be a p-channel FET. In addition, the connections among the transistors Qs and Qd, the capacitor Cst, and the organic light emitting diode LD may be modified.

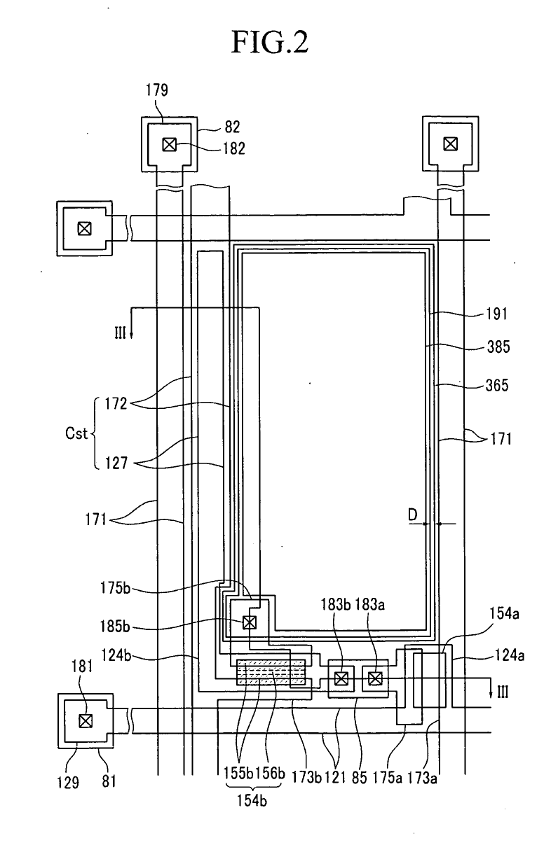

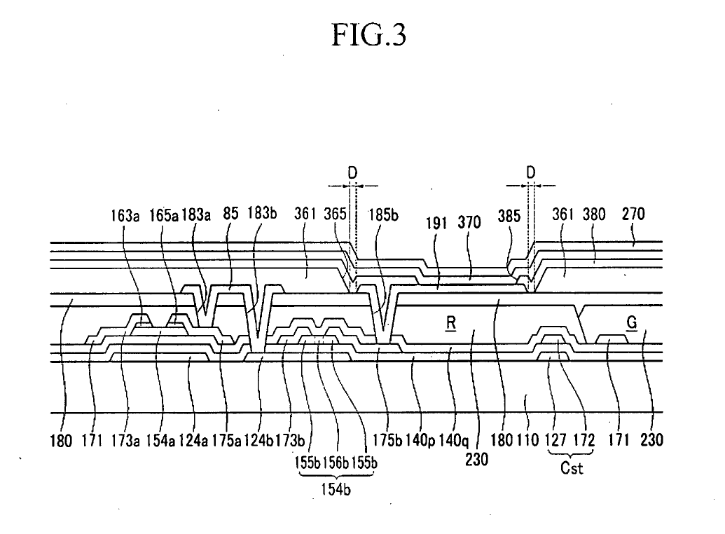

Now, the structure of the organic light emitting device will be described in detail with reference to FIG. 2 and FIG. 3 along with FIG. 1.

FIG. 2 is a layout view of an organic light emitting device according to an exemplary embodiment of the present invention, and FIG. 3 is a cross-sectional view showing the organic light emitting device shown in FIG. 2 taken along line III-III.

An insulating substrate 110, which may be made of transparent glass or plastic, is provided. Here, the insulating substrate 110 may be subjected to a pre-compaction treatment. In the pre-compaction treatment, the substrate is heat-treated at a temperature of about 500° C. to 800° C. such that the substrate is expanded and contracted by the heat.

A plurality of gate lines 121 including a plurality of switching control electrodes 124a and a plurality of driving control electrodes 124b are formed on the substrate 110.

The gate lines 121 extend in one direction of the substrate and include the switching control electrodes 124a extending upward, and an end portion 129 for connection with an external driving circuit.

The driving control electrodes 124b are spaced apart from the gate lines 121, and include a storage electrode 127 extending upward.

The gate lines 121 and the driving control electrodes 124b may be made of a refractory metal such as a molybdenum-containing metal including molybdenum (Mo) or a molybdenum alloy, a chromium-containing metal including chromium (Cr) or a chromium alloy, a titanium-containing metal including titanium (Ti) or a titanium alloy, a tantalum-containing metal including tantalum (Ta) or a tantalum alloy, and a tungsten-containing metal including tungsten (W) or a tungsten alloy, or a low resistance metal such as aluminum (Al), copper (Cu), or silver (Ag).

A driving gate insulating layer 140p is formed on the gate lines 121 and the driving control electrodes 124b. The driving gate insulating layer 140p may be made of silicon nitride (SiNₓ) or silicon oxide (SiO₂) and may have a thickness of about 500 Å to 2,000 Å.

A plurality of driving semiconductors 154b overlapping the driving control electrodes 124b are formed on the driving gate insulating layer 140p. The driving semiconductors 154b may have island shapes, and may be made of a crystalline silicon such as microcrystalline silicon or polycrystalline silicon.

The driving semiconductors 154b each include doped regions 155b and a non-doped region 156b. The doped regions 155b are disposed on both sides of the central non-doped region 156b, and may be made of crystalline silicon doped with an n-type impurity such as phosphorous (P) or a p-type impurity such as boron (B). The non-doped region 156b may be made of an intrinsic semiconductor that is not doped with an impurity and forms the channel of the driving thin film transistor.

A plurality of driving voltage lines 172, which include a plurality of driving input electrodes 173b, and a plurality of driving output electrodes 175b are formed on the driving semiconductors 154b and the driving gate insulating layer 140p.

The driving voltage lines 172 extend substantially in the longitudinal direction to cross the gate lines 121, and transmit a driving voltage. The driving voltage lines 172 include the driving input electrodes 173b, which are formed on the driving semiconductors 154b, and a portion of each driving voltage line 172 overlaps the storage electrode 127 of the corresponding driving control electrode 124b to form a storage capacitor (Cst).

The driving output electrodes 175b are spaced apart from the driving voltage lines 172 and may have an island shape.

The driving input electrodes 173b and the driving output electrodes 175b are respectively disposed on the doped regions 155b of the driving semiconductors 154b, and are opposite to each other with respect to the non-doped regions 156b of the driving semiconductors 154b. Here, the driving input electrodes 173b and the non-doped regions 156b, and the driving output electrodes 175b and the non-doped regions 156b, are spaced apart from each other with an interval therebetween. The regions between the driving input electrodes 173b and the non-doped regions 156b, and the driving output electrodes 175b and the non-doped regions 156b, are offset regions.

The driving voltage lines 172 and the driving output electrodes 175b may be made of the above-described refractory metal, or of a low resistance metal such as aluminum (Al), copper (Cu), or silver (Ag), and may have a single layer structure or a multilayered structure such as molybdenum (Mo)/aluminum (Al)/molybdenum (Mo). In the case of the multilayered structure, the thickness of the molybdenum (Mo)/aluminum (Al)/molybdenum (Mo) may be about 300 Å, about 2,500 Å, and about 1,000 Å, respectively.

A switching gate insulating layer 140q is formed on the driving voltage lines 172 and the driving output electrodes 175b. The switching gate insulating layer 140q may be made of silicon nitride (SiNₓ) and may have a thickness of about 3,000 Å to 4,500 Å.

A plurality of switching semiconductors 154a overlapping the switching control electrodes 124a are formed on the switching gate insulating layer 140q. The switching semiconductor 154a may be made of amorphous silicon and may have a thickness of about 1,500 Å to 2,500 Å.

A plurality of a pair of ohmic contacts 163a and 165a are formed on the switching semiconductors 154a. The ohmic contacts 163a and 165a may be made of amorphous silicon doped with an n-type or p-type impurity, and may have a thickness of 500 Å.

A plurality of data lines 171 including a plurality of switching input electrodes 173a, and a plurality of switching output electrodes 175a are formed on the ohmic contacts 163a and 165a, respectively, and on the switching gate insulating layer 140q.

The data lines 171 extend substantially in the longitudinal direction to cross the gate lines 121, and transmit data signals. A portion of each data line 171 overlaps the corresponding switching semiconductor 154a to form the corresponding switching input electrode 173a.

The switching output electrodes 175a are opposite the switching input electrodes 173a on the switching semiconductors 154a.

The data lines 171 and the switching output electrodes 175a may be made of the above-described refractory metal, or the low resistance metal such as aluminum (Al), copper (Cu), or silver (Ag), and may have a single layer structure or a multilayered structure such as molybdenum (Mo)/aluminum (Al)/molybdenum (Mo). In the case of the multilayered structure, the thickness of the molybdenum (Mo)/aluminum (Al)/molybdenum (Mo) may be about 300 Å, about 2,500 Å, and about 1,000 Å, respectively.

A plurality of red (R), green (G), and blue color filters 230 are formed on the data lines 171 and the switching output electrodes 175a.

A passivation layer 180 is formed on the color filters 230. The passivation layer 180 may be made of an organic material, such as polyacryl, having an excellent flatness characteristic, and the thickness thereof may be in the range of about 2,000 Å to 2 μm.

A plurality of contact holes 183a and 182 exposing the switching output electrodes 175a and end portions 179 of the data lines 171, respectively, are formed in the passivation layer 180 and the color filters 230, a plurality of contact holes 185b exposing the driving output electrode 175b are formed in the passivation layer 180, the color filters 230, and the switching gate insulating layer 140q, and a plurality of contact holes 183b and 181 exposing the driving control electrodes 124b and end portions 129 of the gate lines 121, respectively, are formed in the passivation layer 180, the color filters 230, the switching gate insulating layer 140q, and the driving gate insulating layer 140p.

A plurality of pixel electrodes 191, a plurality of connecting members 85, and a plurality of contact assistants 81 and 82 are formed on the passivation layer 180.

The pixel electrodes 191 are connected to the driving output electrodes 175b through the contact holes 185b, and may be made of a transparent conductor such as ITO or IZO.

The connecting members 85 connect the switching output electrodes 175a and the driving control electrodes 124b through the contact holes 183a and 183b.

The contact assistants 81 and 82 are respectively connected to the end portions 129 and 179 of the gate lines 121 and the data lines 171 through the contact holes 181 and 182. The contact assistants 81 and 82 adhere the end portions 179 and 129 of the data lines 171 and gate lines 121 to outside components, and protect the end portions 179 and 129 of the data lines 171 and gate lines 121.

A pixel-defining layer 361 is formed on the passivation layer 180 and the connecting member 85. The pixel-defining layer 361 surrounds the edges of the pixel electrodes 191 like a bank, and includes a plurality of openings 365 exposing the pixel electrodes 191. The pixel electrodes 191 are disposed in the openings 365, and the distance D from each edge of the pixel electrodes 191 to an edge of the pixel-defining layer 361 forming the openings 365 may be in the range of about 1-2 μm. When the distance D is less than 1 μm, an impurity blocking effect of a blocking film 380, which will be described below may be deteriorated, and when the distance D is more than 2 μm, the aperture ratio may be deteriorated. The pixel-defining layer 361 may be formed of an organic insulating material.

The blocking film 380, which may be made of an inorganic insulating material, is formed on the pixel-defining layer 361. The blocking film 380 may be a single layer of silicon oxide (SiO₂) or silicon nitride (SiNₓ), or a multi-layered structure of silicon oxide (SiO₂) and silicon nitride (SiNₓ). The total thickness of the blocking film 380 may be in the range of 1,000-4,000 Å. When the thickness of the blocking film 380 is less than 1000 Å, the blocking film 380 may be incompletely formed due to the surface roughness of the pixel-defining layer 361, and therefore may not sufficiently block the impurity or moisture flowing in from the color filters 230 or the passivation layer 180. When the thickness of the blocking film 380 is thicker than 4000 Å, the blocking film 380 may cause heavy stress on the beneath layers and it may take too much time to deposit the blocking film 380. The blocking film 380 completely covers the pixel-defining layer 361 and extends in the openings 365 to cover the edges of the pixel electrodes 191. Here, the blocking film 380 contacts the passivation layer 180 between the pixel-defining layer 361 and the pixel electrodes 191, ascends according to the side surfaces of the pixel electrodes 191, and also covers the upper surfaces of the pixel electrodes 191. This structure increases the contact area of the blocking film 380 and the pixel electrodes 191 to more effectively prevent impurities and moisture from the passivation layer 180 and the color filters 230 from penetrating into the organic light emitting member 370. The blocking film 380 has a plurality of openings 385 exposing the central portion of the pixel electrodes 191.

An organic light emitting member 370 is formed on the blocking film 380 and the pixel electrodes 191. The organic light emitting member 370 may have a multi-layered structure including a light emission layer to emit light and an auxiliary layer (not shown) to improve light emitting efficiency.

The emission layer may be made by vertically or horizontally forming red, green, and blue emission layers to emit white light in one pixel. The emission layer may be made of a high molecular weight material, a low molecular weight material, or a mixture thereof that uniquely emits light of one primary color such as red, green, or blue.

The auxiliary layer may include at least one selected of an electron transport layer (not shown) and a hole transport layer (not shown) to achieve a balance of electrons and holes, and an electron injection layer (not shown) and a hole injection layer (not shown) to reinforce the injection of the electrons and the holes.

A common electrode 270 is formed on the light emitting member 370. The common electrode 270 is formed on the whole surface of the substrate, and may be made of an opaque conductor such Au, Pt, Ni, Cu, W, or an alloy thereof.

The common electrode 270 supplies current to the light emitting members 370 in cooperation with the pixel electrodes 191. A pixel electrode 191, a light emitting member 370, and the common electrode 270 form an organic light emitting diode LD having the pixel electrode 191 as an anode and the common electrode 270 as a cathode, or vice versa.

In an exemplary embodiment of the present invention, the pixel-defining layer 361 and the blocking film 380, which covers the pixel-defining layer 361 and the edges of the pixel electrodes 191, are formed to prevent impurities or moisture from the organic passivation layer 180 thereunder or the color filter 230 from penetrating into the organic emission layer of the light emitting member 370.

On the other hand, the interlayer structure or the arrangement structure of the switching thin film transistor Qs and the driving thin film transistor Qd may have various shapes other than that what is described above.

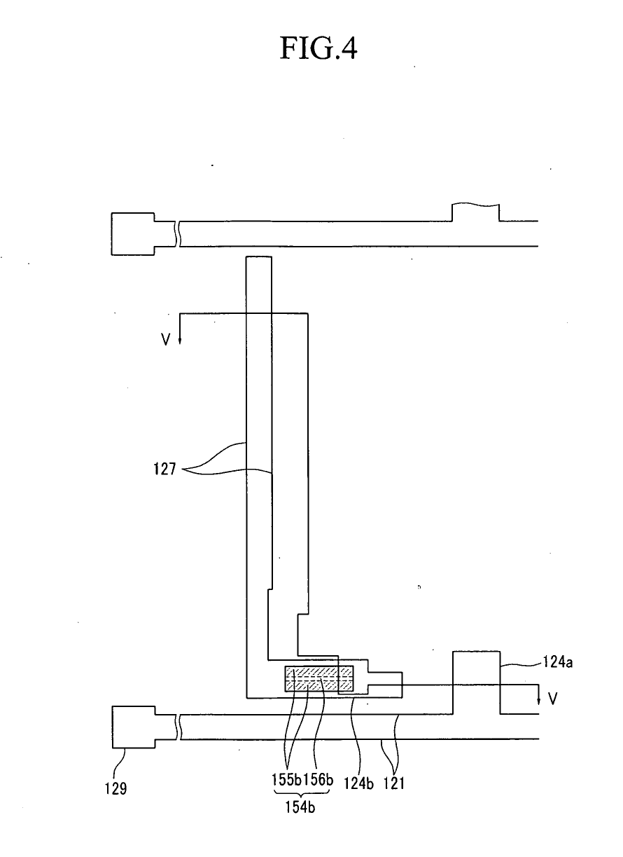

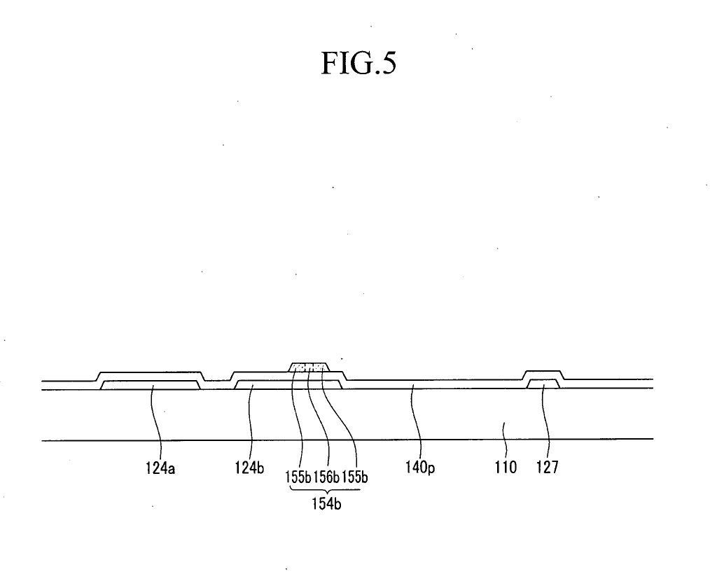

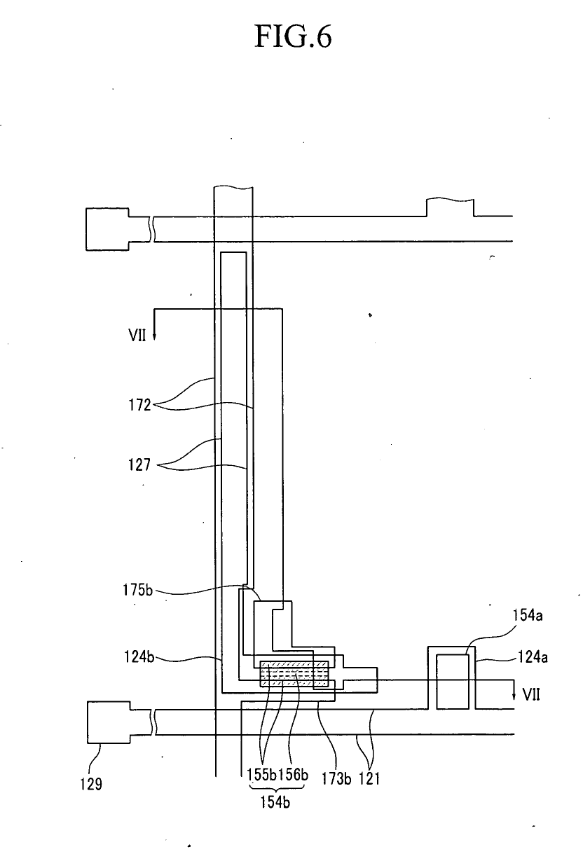

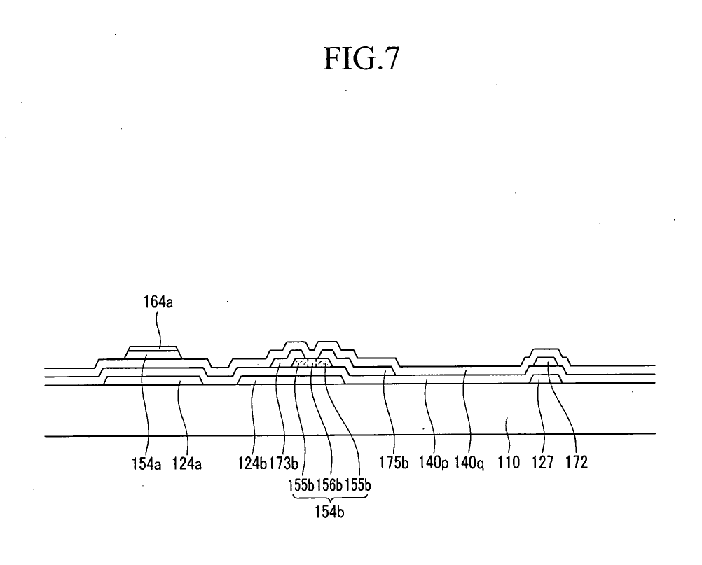

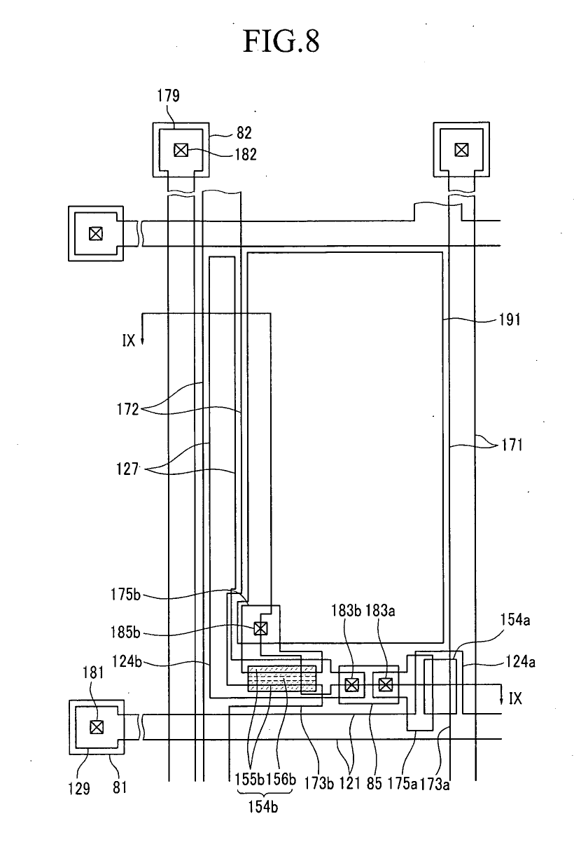

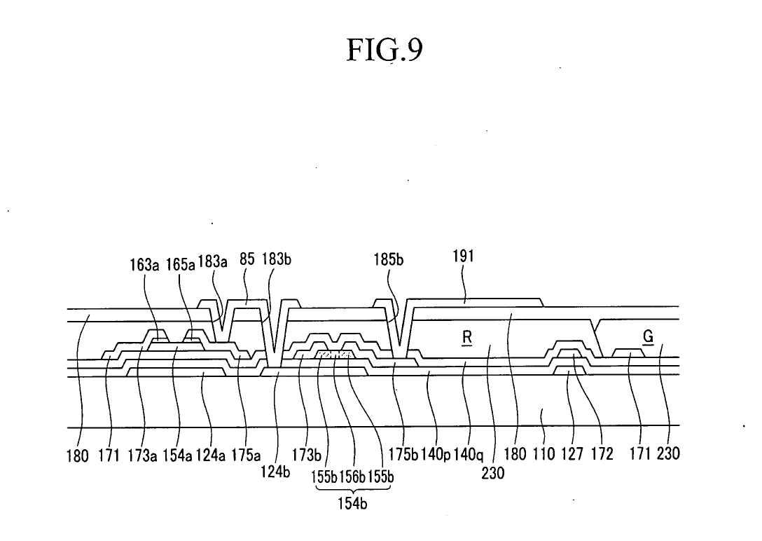

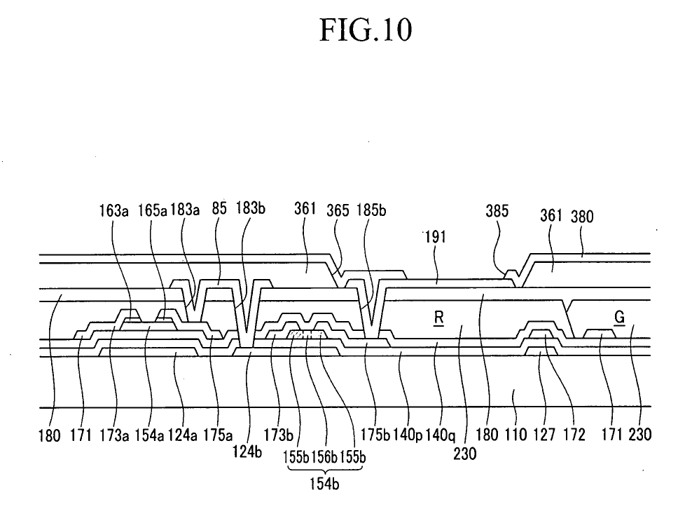

Now, a method of manufacturing the display panel shown in FIG. 2 and FIG. 3 is described with reference to FIG. 4, FIG. 5, FIG. 6, FIG. 7, FIG. 8, FIG. 9, and FIG. 10 as well as FIG. 2 and FIG. 3.

FIG. 4, FIG. 6, and FIG. 8 are layout views sequentially showing the manufacturing method of the organic light emitting device shown in FIG. 2 and FIG. 3, FIG. 5 is a cross-sectional view of the organic light emitting device shown in FIG. 4 taken along line V-V, FIG. 7 is a cross-sectional view of the organic light emitting device shown in FIG. 6 taken along line VII-VII, FIG. 9 is a cross-sectional view of the organic light emitting device shown in FIG. 8 taken along line IX-IX, and FIG. 10 is a cross-sectional view showing a manufacturing step following that shown in FIG. 9.

Firstly, a pre-compaction process is performed on an insulating substrate 110. The pre-compaction process expands and contracts the substrate 110 with heat by performing heat treatment in advance at a high temperature of about 500° C. to 800° C. The pre-compaction process may reduce subsequent expansion or contraction of the substrate 110 by heat during a solidification crystallization process that will be described below, thereby preventing misalignment.

Referring to FIG. 4 and FIG. 5, a metal layer (not shown) is deposited on the insulating substrate 110 having undergone the pre-compaction treatment, and is patterned by photolithography to form a gate line 121 including a switching control electrode 124a and an end portion 129, and a driving control electrode 124b including a storage electrode 127. The driving gate insulating layer 140p, which may be made of silicon oxide, and the first amorphous silicon layer are deposited on the whole surface of the substrate 110 including the gate line 121 and the driving control electrode 124b.

A doping stopper is formed at a position overlapping the driving control electrode 124b, and the first amorphous silicon layer may be doped with an impurity using the doping stopper as a mask. The impurity may be p-type impurity such as boron, or an n-type impurity such as phosphorous.

Next, the doping stopper is removed, and then the first amorphous silicon layer may be patterned by photolithography to form driving semiconductor 154b with an island shape. The driving semiconductor 154b includes doped regions 155b and a non-doped region 156b. Next, the driving semiconductor 154b is crystallized. For the crystallization, solid phase crystallization (SPC), rapid thermal annealing (RTA), liquid phase recrystallization (LPR), or excimer laser annealing (ELA) may be used. Solid phase crystallization is advantageous because it may be used to easily crystallize a large area. In the crystallization, the activation of the driving semiconductor 154b may be executed after doping the doped regions 155b with the impurity.

Next, referring to FIG. 6 and FIG. 7, a metal layer is deposited on the driving semiconductor 154b and the driving gate insulating layer 140p, and is patterned by photolithography to form a driving voltage line 172, which includes a driving input electrode 173b, and a driving output electrode 175b. Here, the driving input electrode 173b and the driving output electrode 175b are each spaced apart from the non-doped region 156b of the driving semiconductor 154b by an interval.

Next, a switching gate insulating layer 140q, a second amorphous silicon layer (not shown), and a silicon layer (not shown) doped with an impurity are deposited on the whole surface of the substrate including the driving voltage line 172 and the driving output electrode 175b, and the silicon layer doped with an impurity and the second amorphous silicon layer may be patterned by photolithography to form a switching semiconductor 154a and an ohmic contact layer 164a with an island shape.

A metal layer is then deposited on the ohmic contact layer 164a and the switching gate insulating layer 140q and patterned by photolithography to form a data line 171, which includes a switching input electrode 173a, and a switching output electrode 175a.

The ohmic contact layer 164a is etched using the switching input electrode 173a and the switching output electrode 175a as a mask to form a pair of ohmic contacts 163a and 165a (see FIG. 9). Then, a photoresist including pigments is repeatedly coated, exposed, and developed to form color filters 230 of red, green, and blue. Here, contact holes may be formed in the color filters 230.

Next, a passivation layer 180 is deposited on the whole surface of the substrate and patterned by photolithography to form a plurality of contact holes 181, 182, 183a, 183b, and 185b, and a transparent conductive layer such as ITO is deposited on the passivation layer 180 and patterned by photolithography to form a pixel electrode 191, a connecting member 85, and contact assistants 81 and 82. The passivation layer 180 may be made of an organic material having photosensitivity, and the contact holes 181, 182, 183a, 183b, and 185b may be formed by a photo process.

Next, referring to FIG. 10, an organic layer is coated on the pixel electrode 191, the connecting member 85, and the passivation layer 180, and is exposed and developed to form a pixel-defining layer 361 including a plurality of openings 365.

Next, an inorganic layer of silicon nitride or silicon oxide is deposited on the pixel-defining layer 361 and patterned by photolithography to form a blocking film 380 covering the pixel-defining layer 361 and the edges of the pixel electrode 191, and having an opening 385 exposing the central portion of the pixel electrode 191.

Next, referring to FIG. 2 and FIG. 3, an organic light emitting member 370 including a hole transport layer (not shown) and an emission layer (not shown) is formed on the blocking film 380 and the pixel electrode 191. The organic light emitting member 370 may be formed by a deposition method.

Finally, a common electrode 270 is formed on the organic light emitting member 370.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An organic light emitting device, comprising:
a first signal line and a second signal line crossing each other;
a switching thin film transistor connected to the first signal line and the second signal line;
a driving thin film transistor connected to the switching thin film transistor;
an organic layer covering the first signal line, the second signal line, the switching thin film transistor, and the driving thin film transistor;
a pixel electrode formed on the organic layer and connected to the driving thin film transistor;
a pixel-defining layer disposed on the organic layer and enclosing the pixel electrode;
a blocking film covering the pixel-defining layer and edges of the pixel electrode, the blocking film comprising an inorganic insulating layer;
a light emitting member disposed on the pixel electrode; and
a common electrode disposed on the light emitting member.

2. The organic light emitting device of claim 1, wherein the blocking film has the thickness of 1,000-4,000 Å.

3. The organic light emitting device of claim 2, wherein the blocking film is a single layer of silicon nitride or silicon oxide, or a multilayered structure comprising silicon nitride or silicon oxide.

4. The organic light emitting device of claim 3, wherein the distance between the pixel-defining layer and each edge of the pixel electrode is in the range of 1-2 μm.

5. The organic light emitting device of claim 4, further comprising:
a color filter disposed under the organic layer.

6. The organic light emitting device of claim 5, wherein the light emitting member emits white light.

7. The organic light emitting device of claim 6, wherein the light emitting member is disposed on the blocking film.

8. The organic light emitting device of claim 1, wherein the distance between the pixel-defining layer and each edge of the pixel electrode is in the range of 1-2 μm.

9. The organic light emitting device of claim 8, further comprising:
a color filter disposed under the organic layer.

10. The organic light emitting device of claim 9, wherein the light emitting member emits white light.

11. The organic light emitting device of claim 10, wherein the light emitting member is disposed on the blocking film.

12. A method for manufacturing an organic light emitting device comprising:
forming wiring and a thin film transistor on a substrate;
forming an organic layer on the wiring and the thin film transistor;
forming a pixel electrode on the organic layer, the pixel electrode connected to the thin film transistor;
forming a pixel-defining layer on the organic layer, the pixel-defining layer enclosing the pixel electrode;
forming a blocking film covering the pixel-defining layer and edges of the pixel electrode;
forming an organic light emitting member on the pixel electrode; and
forming a common electrode on the organic light emitting member.

13. The method of claim 12, wherein forming the blocking film comprises depositing an inorganic insulating layer and patterning it by photolithography.

14. The method of claim 13, wherein the blocking film has a thickness of 1,000-4,000 Å.

15. The method of claim 14, wherein the blocking film is a single layer of silicon nitride or silicon oxide, or a multilayered structure comprising silicon nitride or silicon oxide.

16. The method of claim 15, further comprising:
forming a color filter after forming the wiring and the thin film transistor on the substrate, and before the forming the organic layer.

17. The method of claim 16, wherein the organic light emitting member is disposed on the pixel electrode and the blocking film.

18. The method of claim 17, wherein the organic light emitting member emits white light.

19. The method of claim 12, wherein the blocking film is formed directly on the pixel defining layer, the organic layer, and the pixel electrode.

20. The organic light emitting device of claim 1, wherein the blocking film is directly on the pixel defining layer, the organic layer, and the pixel electrode.
